(19) United States
(12) Patent Application Publication
(10) Pub. No.: US 2020/0251373 A1
(43) Pub. Date: Aug. 6, 2020

(54) MICRO LED TRANSFER HEAD

(71) Applicant: POINT ENGINEERING CO., LTD., Asan (KR)

(72) Inventors: Bum Mo AHN, Suwon (KR); Seung Ho PARK, Hwaseong (KR); Sung Hyun BYUN, Hwaseong (KR)

(21) Appl. No.: 16/777,794

(22) Filed: Jan. 30, 2020

(30) Foreign Application Priority Data
Feb. 1, 2019 (KR) 10-2019-0013879

(51) Int. Cl. H01L 21/683; H01L 33/00; H05K 13/04

(52) U.S. Cl. CPC H01L 21/6838; H05K 13/0409; H01L 33/0095

(57) ABSTRACT

The present invention relates to a micro LED transfer head transferring a micro light-emitting diode (micro LED) from a first substrate to a second substrate. More particularly, the present invention relates to a micro LED transfer head, in which the lowering position of the micro LED transfer head is limited.

### CROSS REFERENCE TO RELATED APPLICATION

The present application claims priority to Korean Patent Application No. 10-2019-0013879, filed Feb. 1, 2019, the entire contents of which is incorporated herein for all purposes by this reference.

### BACKGROUND OF THE INVENTION

### Field of the Invention

The present invention relates to a micro LED transfer head transferring a micro light-emitting diode (micro LED) from a first substrate to a second substrate.

### Description of the Related Art

Currently, the display market remains dominated by LCDs, but OLEDs are quickly replacing LCDs and emerging as mainstream products. In the current situation in which display makers are rushing to participate in the OLED market, micro light-emitting diode (hereinafter, referred to as micro LED) displays have emerged as another type of next generation display. A micro LED is not a package type covered with molding resin or the like but a piece obtained by cutting out a wafer used for crystal growth. Liquid crystal and organic materials are the core materials of LCDs and OLEDs, respectively, whereas the micro LED display uses 1 μm to 100 μm of LED chips as a light emitting material.

Since the term “micro LED” emerged in a patent “MICRO-LED ARRAYS WITH ENHANCED LIGHT EXTRACTION” in 1999 (Korean Patent No. 10-0731673, hereinafter referred to as ‘Related Art 1’) disclosed by Cree Inc., related research papers based thereon were subsequently published. In order to apply micro LEDs to a display, it is necessary to develop a customized microchip based on a flexible material and/or a flexible device using a micro LED device, and techniques of transferring micrometer-sized LED chips and accurately mounting the LED chips on a display pixel electrode are required.

Particularly, with regard to the transfer of the micro LED device to a display substrate, as the LED size is reduced to 1 μm to 100 μm, it is impossible to use a conventional pick-and-place machine, and a technology of a transfer head for higher precision is required. With respect to such a technology of a transfer head, several structures have been proposed as described below.

Luxvue Technology Corp., USA, proposed a method of transferring a micro LED using an electrostatic head (Korean Patent Application Publication No. 10-2014-0112486, hereinafter referred to as ‘Related Art 2’). A transfer principle of Related Art Document 2 is that a voltage is applied to a head unit made of a silicone material so that the head unit comes into close contact with a micro LED due to electrification. However, this method may cause damage to micro LEDs due to electrification caused by the voltage applied to the head unit during induction of static electricity.

X-Celeprint Limited, USA, proposed a method of using an elastic polymer material as a transfer head and transferring micro LEDs positioned on a wafer to a desired substrate (Korean Patent Application Publication No. 10-2017-0019415, hereinafter referred to as ‘Related Art 3’). According to Related Art Document 3, there is no damage to micro LEDs as compared with the above-mentioned electrostatic head. However, adhesive force of the elastic transfer head is required to be higher than that of a target substrate in the transfer process to transfer micro LEDs stably, and an additional process for forming an electrode is required. In addition, maintaining adhesive force of the elastic polymer material is an important factor.

Korea Photonics Technology Institute proposed a method of transferring a micro LED using a ciliary adhesive-structured head (Korean Patent No. 10-1754528, hereinafter referred to as ‘Related Art 4’). However, in Related Art Document 4, it is difficult to manufacture a ciliary adhesive structure.

Korea Institute of Machinery and Materials has proposed a method of transferring a micro LED using a roller coated with an adhesive (Korean Patent No. 10-1757404, hereinafter referred to as ‘Related Art 5’). However, Related Art Document 5 has a problem in that continuous use of the adhesive is required, and the micro LED may be damaged when pressed with the roller.

Samsung Display Co., Ltd proposed a method of transferring micro LEDs to an array substrate according to electrostatic induction by applying a negative voltage to first and second electrodes of the array substrate in a state in which the array substrate is immersed in a solution (Korean Patent Application Publication No. 10-2017-0026959, hereinafter referred to as ‘Related Art 6’). However, Related Art Document 6 has a problem in that a solution is required since the micro LED is immersed in the solution to transfer to the array substrate, and a drying process is required.

LG Electronics Inc. proposed a method in which a head holder is disposed between multiple pick-up heads and a substrate and a shape of the head holder is deformed by movement of the multiple pick-up heads such that the multiple pick-up heads are allowed to move freely (Korean Patent Application Publication No. 10-2017-0024906, hereinafter referred to as ‘Related Art 7’). However, Related Art Document has a problem in that a process of applying a bonding material to the pick-up heads is required because the bonding material having adhesive force is required to be applied to bonding surfaces of the multiple pick-up heads to transfer the micro LED.

In order to solve the above problems of Related Art Documents, it may be considered that microholes in which a holding force for micro LEDs is generated are provided in a transfer head for transferring the micro LEDs. The holes may be formed in a holding part constituting the transfer head. The transfer head can hold the micro LEDs by the holding force generated in the holes of the holding part In this case, the holding part of the transfer head may be made of a material having a high degree of hardness to prevent product deformation.

The transfer head as described above may hold micro LEDs 100 chipped on a silicon substrate 101 (e.g., a growth substrate 101 or a carrier substrate). The substrate 101 may undergo warpage due to thermal deformation during a high temperature process.

FIGS. 1A and B are views schematically illustrating a technology underlying the present invention. The letter “h” illustrated in FIGS. 1A and 1B denotes a warpage height of a first substrate 101. The substrate 101 may warp in a crying (∩) shape (hereinafter, this warpage is referred to as “crying warpage”) as illustrated in FIG. 1A, or may warp in a smiling (∪) shape (hereinafter, this warpage is referred to as “smiling warpage”) as illustrated in FIG. 1B.

Due to the warpage of the substrate 101, the height of each chipped micro LED 100 on the substrate 101 may vary. Due thereto, when the micro LEDs 100 are held, a contact position of a holding part 2 for holding each of the micro LEDs 100 may vary, thereby causing damage to the micro LEDs 100.

Referring to FIG. 1A, as illustrated in FIG. 1A, a transfer head 1000 is lowered to hold the micro LEDs 100 of the substrate 101 in which the crying warpage has occurred. The substrate 101 in which the crying warpage has occurred may have a shape convexly warped upwardly in the drawing of FIG. 1A. Micro LEDs 100 which are located on a convex portion of the substrate 101 may first come into contact with a holding surface of the holding part 2. The transfer head 1000 may then be lowered to hold all the micro LEDs 100 on the first substrate 101. In this case, the micro LEDs 100 which are first in contact with the holding surface may be damaged while being excessively pressurized by the holding part 2. Due to the fact that the holding part 2 is made of a material having a high degree of hardness, the holding part 2 may cause a micro LED damage problem more easily upon contact with the micro LEDs 100.

In addition, as illustrated in FIG. 1B, the transfer head 1000 is lowered to hold the micro LEDs 100 of the substrate 101 in which the smiling warpage has occurred. The substrate 101 in which the smiling warpage has occurred may have a shape concavely warped downwardly in the drawing of FIG. 1B. Due to the warpage of the substrate 101, a micro LED 100 located at a highest position on the substrate 101 in FIG. 1B may first come into contact with the holding surface of the holding part 2. The transfer head 1000 may then be lowered gradually to hold micro LEDs 100 which remain without contact. Herein, the holding part 2 is lowered while pressurizing the micro LED 100 which is first in contact therewith. This may result in a problem of damage to the micro LEDs 100.

As such, in the transfer head 1000 having the holding part 2 made of a material having a high degree of hardness to prevent product deformation, the contact position for holding each micro LED 100 may vary when the warpage of the substrate 101 occurs. As a result, the micro LED 100 which is first held on the holding part 2 may be excessively pressurized, which may lead to the problem of damage to the micro LEDs 100. Accordingly, the applicant of the present invention has proposed a method that can improve the problems of the related art described above and to compensate for the disadvantages of the technology underlying the present invention.

The foregoing is intended merely to aid in the understanding of the background of the present invention, and is not intended to mean that the present invention falls within the purview of the related art that is already known to those skilled in the art.

### Documents of Related Art

(Patent Document 1) Korean Patent No. 10-0731673;

(Patent Document 2) Korean Patent Application Publication No. 10-2014-0112486;

(Patent Document 3) Korean Patent Application Publication No. 10-2017-0019415;

(Patent Document 4) Korean Patent No. 10-1754528;

(Patent Document 5) Korean Patent No. 10-1757404;

(Patent Document 6) Korean Patent Application Publication No. 10-2017-0026959; and

(Patent Document 7) Korean Patent Application Publication No. 10-2017-0024906

### SUMMARY OF THE INVENTION

Accordingly, the present invention has been made keeping in mind the above problems occurring in the related art, and an objective of the present invention is to provide a micro LED transfer head that can prevent damage to micro LEDs when holding the micro LEDs even when warpage of a substrate occurs.

In order to achieve the above objective, according to one aspect of the present invention, there is provided a micro LED transfer head transferring a micro LED from a first substrate to a second substrate, the micro LED transfer head including: a holding part holding the micro LED; and a buffer member provided around the holding part and protruding downwardly further than the holding part.

Furthermore, the buffer member may be provided discontinuously around the holding part.

Furthermore, the buffer member may be provided continuously around the holding part.

Furthermore, the buffer member may be polydimethysiloxane (PDMS).

As described above, the micro LED transfer head according to the present invention is characterized in that the lowering position of the micro LED transfer head is limited through the member made of an elastically deformable material. Therefore, it is possible to prevent the problem of micro LED damage due to excessive lowering of the micro LED transfer head. In addition, it is also possible for the micro LED transfer head to perform warpage alleviation and flatness control of the substrate on which the micro LEDs when being lowered, thereby achieving increased micro LED holding efficiency.

### BRIEF DESCRIPTION OF THE DRAWINGS

The above and other objectives, features, and other advantages of the present invention will be more clearly understood from the following detailed description when taken in conjunction with the accompanying drawings, in which:

FIGS. 1A and B are views schematically illustrating a technology underlying the present invention;

FIG. 2 is a view illustrating micro LEDs to be transferred by an embodiment of the present invention;

FIG. 3 is a view illustrating a micro LED structure transferred to a display substrate and mounted by the embodiment of the present invention;

FIG. 4 is a view schematically illustrating a micro LED transfer head according to an embodiment of the present invention;

FIG. 5 is a view illustrating FIG. 4 when viewed from below;

FIGS. 6A, 6B, 6C, and 6D are views schematically illustrating an operation sequence of FIG. 4;

FIG. 7 is a view schematically illustrating a micro LED transfer head according to a first modification of the present invention;

FIG. 8 is a view illustrating FIG. 7 when viewed from below; and

FIG. 9 is a view schematically illustrating a micro LED transfer head according to a second modification of the present invention.

### DETAILED DESCRIPTION OF THE INVENTION

Contents of the description below merely exemplify the principle of the invention. Therefore, those of ordinary skill in the art may implement the theory of the invention and invent various apparatuses which are included within the concept and the scope of the invention even though it is not clearly explained or illustrated in the description. Furthermore, in principle, all the conditional terms and embodiments listed in this description are clearly intended for the purpose of understanding the concept of the invention, and one should understand that this invention is not limited the exemplary embodiments and the conditions.

The above described objectives, features, and advantages will be more apparent through the following detailed description related to the accompanying drawings, and thus those of ordinary skill in the art may easily implement the technical spirit of the invention.

The embodiments of the present invention will be described with reference to cross-sectional views and/or perspective views which schematically illustrate ideal embodiments of the present invention. For explicit and convenient description of the technical content, sizes or thicknesses of films and regions and diameters of holes in the figures may be exaggerated. Therefore, variations from the shapes of the illustrations as a result, for example, of manufacturing techniques and/or tolerances, are to be expected. In addition, a limited number of multiple micro LEDs are illustrated in the drawings. Thus, the embodiments should not be construed as limited to the particular shapes of regions illustrated herein but are to include deviations in shapes that result, for example, from manufacturing.

Wherever possible, the same reference numerals will be used throughout different embodiments and the description to refer to the same or like elements or parts. In addition, the configuration and operation already described in other embodiments will be omitted for convenience.

Hereinafter, exemplary embodiments of the present invention will be described in detail with reference to the accompanying drawings.

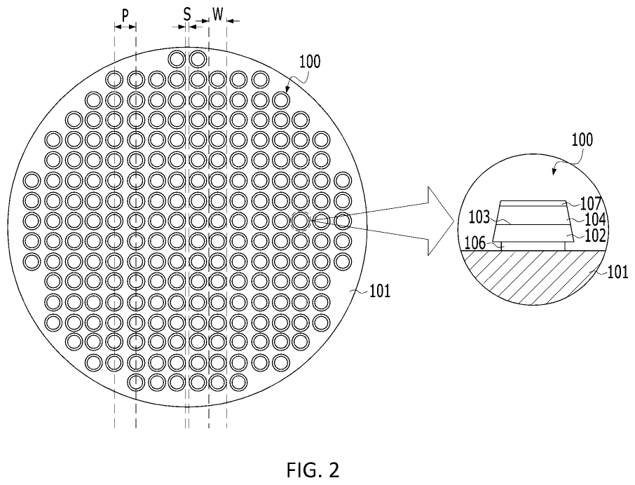

FIG. 2 is a view illustrating multiple micro LEDs 100 to be transferred by a micro LED transfer head 1 according to an embodiment of the present invention. The micro LEDs 100 are fabricated and disposed on a growth substrate 101.

The growth substrate 101 may be embodied by a conductive substrate or an insulating substrate. For example, the growth substrate 101 may be made of at least one selected from among the group consisting of sapphire, SiC, Si, GaAs, GaN, ZnO, GaP, InP, Ge, and Ga₂O₃.

Each of the micro LEDs 100 may include: a first semiconductor layer 102; a second semiconductor layer 104; an active layer 103 provided between the first semiconductor layer 102 and the second semiconductor layer 104; a first contact electrode 106; and a second contact electrode 107.

The first semiconductor layer 102, the active layer 103, and the second semiconductor layer 104 may be formed by performing metalorganic chemical vapor deposition (MOCVD), chemical vapor deposition (CVD), plasma-enhanced chemical vapor deposition (PECVD), molecular-beam epitaxy (MBE), hydride vapor phase epitaxy (HVPE), or the like.

The first semiconductor layer 102 may be implemented, for example, as a p-type semiconductor layer. A p-type semiconductor layer may be made of a semiconductor material having a composition formula of InxAlyGa1-x-yN (0≤x≤1, 0≤y≤1, 0≤x+y≤1) selected from among, for example, GaN, AlN, AlGaN, InGaN, InN, InAlGaN, AlInN, and the like, and the layer may be doped with a p-type dopant such as Mg, Zn, Ca, Sr, or Ba.

The second semiconductor layer 104 may be implemented, for example, as an n-type semiconductor layer. An n-type semiconductor layer may be made of a semiconductor material having a composition formula of InxAlyGa1-x-yN (0≤x≤1, 0≤y≤1, 0≤x+y≤1) selected from among, for example, GaN, AlN, AlGaN, InGaN, InNInAlGaN, AlInN, and the like, and the layer may be doped with an n-type dopant such as Si, Ge, or Sn.

However, the present invention is not limited to this. The first semiconductor layer 102 may be implemented as an n-type semiconductor layer, and the second semiconductor layer 104 may be implemented as a p-type semiconductor layer.

The active layer 103 is a region where electrons and holes are recombined. As the electrons and the holes are recombined, the active layer 103 transits to a low energy level and generates light having a wavelength corresponding thereto. The active layer 103 may be made of a semiconductor material having a composition formula of InxAlyGa1-x-yN (0≤x≤1, 0≤y≤1, 0≤x+y≤1) and may have a single quantum well structure or a multi-quantum well (MQW) structure. In addition, the active layer 103 may have a quantum wire structure or a quantum dot structure.

The first semiconductor layer 102 may be provided with the first contact electrode 106, and the second semiconductor layer 104 may be provided with the second contact electrode 107. The first contact electrode 106 and/or the second contact electrode 107 may include at least one layer and may be made of various conductive materials including a metal, conductive oxide, and conductive polymer.

The multiple micro LEDs 100 formed on the growth substrate 101 are separated into individual pieces by cutting along a cutting line using a laser or the like or by etching. Then, it is possible to separate the individual micro LEDs 100 from the growth substrate 101 by a laser lift-off process.

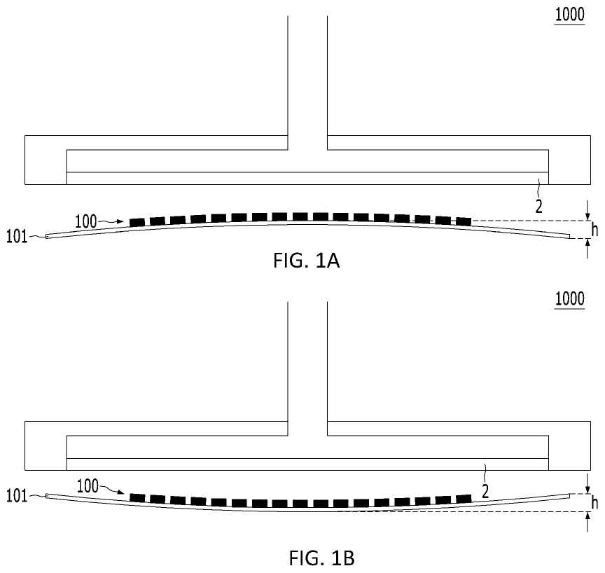

In FIG. 1, the letter “P” denotes a pitch distance between the micro LEDs 100, “S” denotes a separation distance between the micro LEDs 100, and “W” denotes a width of each micro LED 100.

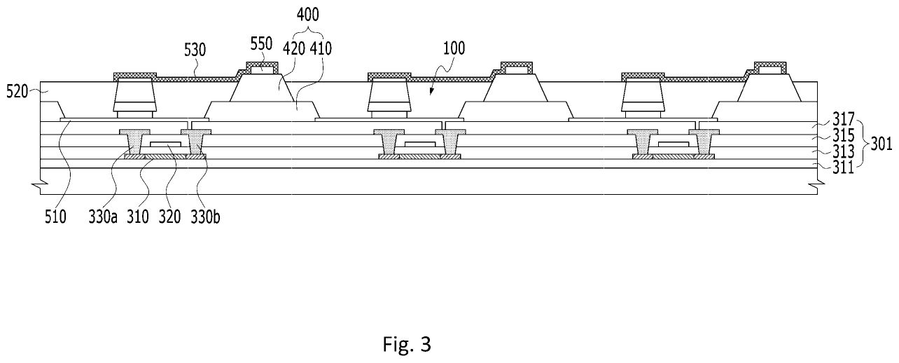

FIG. 3 is a view illustrating a micro LED structure in which the micro LEDs are transferred and mounted to a display substrate 301 by the micro LED transfer head according to the embodiment of the present invention.

The display substrate 301 may include various materials.

For example, the display substrate 301 may be made of a transparent glass material having SiO₂ as a main component. However, materials of the display substrate 301 are not limited to this. The display substrate 301 may be made of a transparent plastic material and thus have solubility. The plastic material may be an organic substance selected from among the group consisting of organic insulating substances, including polyethersulfone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose triacetate (TAC), and cellulose acetate propionate (CAP).

In the case of a bottom emission type in which an image is implemented in a direction of the display substrate 301, the display substrate 301 is required to be made of a transparent material. However, in the case of a top emission type in which an image is implemented in a direction opposite to the display substrate 301, the display substrate 301 is not necessarily required to be made of a transparent material. In this case, the display substrate 301 may be made of metal.

In the case of forming the display substrate 301 using metal, the display substrate 301 may be made of at least one metal selected from among the group consisting of iron, chromium, manganese, nickel, titanium, molybdenum, stainless steel (SUS), Invar alloy, Inconel alloy, and Kovar alloy, but is not limited thereto.

The display substrate 301 may include a buffer layer 311. The buffer layer 311 provides a flat surface and blocks foreign matter or moisture from penetrating therethrough. For example, the buffer layer 311 may contain an inorganic substance such as silicon oxide, silicon nitride, silicon oxynitride, aluminum oxide, aluminum nitride, titanium oxide, and titanium nitride, or an organic substance such as polyimide, polyester, and acrylic. Alternatively, the buffer layer 311 may be formed as a multi-laminate of the exemplified substances.

A thin-film transistor (TFT) may include an active layer 310, a gate electrode 320, a source electrode 330a, and a drain electrode 330b.

Hereinafter, a case where a TFT is a top gate type in which the active layer 310, the gate electrode 320, the source electrode 330a, and the drain electrode 330b are sequentially formed will be described. However, the present embodiment is not limited thereto, and various types of TFTs such as a bottom gate TFT may be employed.

The active layer 310 may contain a semiconductor material, such as amorphous silicon and polycrystalline silicon. However, the present embodiment is not limited thereto, and the active layer 310 may contain various materials. As an alternative embodiment, the active layer 310 may contain an organic semiconductor material or the like.

As another alternative embodiment, the active layer 310 may contain an oxide semiconductor material. For example, the active layer 310 may contain an oxide of a metal element selected from Groups 12, 13, and 14 elements such as zinc (Zn), indium (In), gallium (Ga), tin (Sn), cadmium (Cd), and germanium (Ge), and a combination thereof.

A gate insulating layer 313 is formed on the active layer 310. The gate insulating layer 313 serves to isolate the active layer 310 and the gate electrode 320. The gate insulating layer 313 may be formed as a multilayer or a single layer of a film made of an inorganic substance such as silicon oxide and/or silicon nitride.

The gate electrode 320 is provided on the gate insulating layer 313. The gate electrode 320 may be connected to a gate line (not illustrated) applying an on/off signal to the TFT.

The gate electrode 320 may be made of a low-resistivity metal. In consideration of adhesion with an adjacent layer, surface flatness of layers to be stacked, and processability, the gate electrode 320 may be formed as a multilayer or a single layer, which is made of at least one metal selected from among the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

An interlayer insulating film 315 is provided on the gate electrode 320. The interlayer insulating film 315 isolates the source electrode 330a, the drain electrode 330b, and the gate electrode 320. The interlayer insulating film 315 may be formed as a multilayer or single layer of a film made of an inorganic substance. For example, the inorganic substance may be a metal oxide or a metal nitride. Specifically, the inorganic substance may include silicon dioxide (SiO₂), silicon nitrides (SiNx), silicon oxynitride (SiON), aluminum oxide (Al₂O₃), titanium dioxide (TiO₂), tantalum pentoxide (Ta₂Os), hafnium dioxide (HfO₂), or zirconium dioxide (ZrO₂).

The source electrode 330a and the drain electrode 330b are provided on the interlayer insulating film 315. The source electrode 330a and the drain electrode 330b may be formed as a multilayer or a single layer, which is made of at least one metal selected from among the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The source electrode 330a and the drain electrode 330b are electrically connected to a source region and a drain region of the active layer 310, respectively.

A planarization layer 317 is provided on the TFT. The planarization layer 317 is configured to cover the TFT, thereby eliminating a height difference caused by the TFT and planarizing the top surface. The planarization layer 317 may be formed as a single layer or a multilayer of a film made of an organic substance. The organic substance may include a general-purpose polymer such as polymethyl methacrylate (PMMA) and polystyrene (PS); a polymer derivative having a phenol group; an acrylic polymer, an imide-based polymer, an arylether-based polymer, an amide-based polymer, a fluorine-based polymer, a p-xylene-based polymer, a vinyl alcohol-based polymer; and a blend thereof. In addition, the planarization layer 317 may be formed as a multi-laminate of an inorganic insulating layer and an organic insulating layer.

A first electrode 510 is provided on the planarization layer 317. The first electrode 510 may be electrically connected to the TFT. Specifically, the first electrode 510 may be electrically connected to the drain electrode 330b through a contact hole formed in the planarization layer 317. The first electrode 510 may have various shapes. For example, the first electrode 510 may be patterned in an island layout.

A bank layer 400 defining a pixel region may be disposed on the planarization layer 317. The bank layer 400 may include a recess where each of the micro LEDs 100 will be received. The bank layer 400 may include, for example, a first bank layer 410 defining the recess. A height of the first bank layer 410 may be determined by a height and viewing angle of the micro LED 100. A size (width) of the recess may be determined by resolution, pixel density, and the like, of a display device. In an embodiment, the height of the micro LED 100 may be greater than the height of the first bank layer 410. The recess may have a quadrangular cross-section. However, the present invention is not limited thereto. For example, the recess may have various cross-section shapes, such as polygonal, rectangular, circular, conical, elliptical, and triangular.

The bank layer 400 may further include a second bank layer 420 on the first bank layer 410. The first bank layer 410 and the second bank layer 420 have a height difference, and the second bank layer 420 may be smaller in width than the first bank layer 410. A conductive layer 550 may be disposed on the second bank layer 420. The conductive layer 550 may be disposed in a direction parallel to a data line or a scan line, and may be electrically connected to a second electrode 530. However, the present invention is not limited thereto. The second bank layer 420 may be omitted, and the conductive layer 550 may be disposed on the first bank layer 410. Alternatively, the second bank layer 420 and the conductive layer 500 may be omitted, and the second electrode 530 may be formed over the entire display substrate 301 such that the second electrode 530 serves as a shared electrode that pixels P share. The first bank layer 410 and the second bank layer 420 may include a material absorbing at least a part of light, a light reflective material, or a light scattering material. The first bank layer 410 and the second bank layer 420 may include an insulating material that is translucent or opaque to visible light (e.g., light in a wavelength range of 380 nm to 750 nm).

For example, the first bank layer 410 and the second bank layer 420 may be made of a thermoplastic such as polycarbonate (PC), polyethylene terephthalate (PET), polyethersulfone, polyvinyl butyral, polyphenylene ether, polyamide, polyetherimide, a norbornene system resin, a methacrylic resin, and a cyclic polyolefin-based resin; a thermosetting plastic such as an epoxy resin, a phenolic resin, a urethane resin, an acrylic resin, a vinyl ester resin, an imide-based resin, an urethane-based resin, a urea resin, and melamine resin; or an organic insulating substance such as polystyrene, polyacrylonitrile, and polycarbonate, but are not limited thereto.

As another example, the first bank layer 410 and the second bank layer 420 may be made of an inorganic insulating substance such as inorganic oxide or inorganic nitride including SiOx, SiNx, SiNxOy, AlOx, TiOx, TaOx, or ZnOx, but are not limited thereto. In an embodiment, the first bank layer 410 and the second bank layer 420 may be made of an opaque material such as a black matrix material. The insulating black matrix material may include an organic resin; a resin or a paste including a glass paste and a black pigment; metal particles such as nickel, aluminum, molybdenum, or an alloys thereof; metal oxide particles (e.g., chromium oxide); metal nitride particles (e.g., chromium nitride); or the like.

In a modification, the first bank layer 410 and the second bank layer 420 may be a distributed Bragg reflectors (DBRs) having high reflectivity or mirror reflectors made of a metal.

Each of the micro LEDs 100 is disposed in each recess. The micro LED 100 may be electrically connected to the first electrode 510 at the recess.

The micro LED 100 emits light having wavelengths of different colors such as red, green, blue, white, and the like. With the micro LED 100, it is possible to realize white light by using a fluorescent material or by combining colored lights. The micro LED 100 has a size of 1 μm to 100 μm. The micro LEDs 100 may be picked up from the growth substrate 101 individually or collectively by the transfer head according to the embodiment of the present invention, transferred to the display substrate 301, and received in the respective recesses of the display substrate 301.

The micro LED 100 includes a p-n diode, the first contact electrode 106 disposed on one side of the p-n diode, and the second contact electrode 107 disposed on the opposite side of the first contact electrode 106. The first contact electrode 106 may be connected to the first electrode 510, and the second contact electrode 107 may be connected to the second electrode 530.

The first electrode 510 may include: a reflective layer made of Ag, Mg, Al, Pt, Pd, Au, Ni, Nd, Ir, Cr, or a compound thereof; and a transparent or translucent electrode layer provided on the reflective layer. The transparent or translucent electrode layer may include at least one selected from among the group consisting of indium tin oxide (ITO), indium zinc oxide (IZO), zinc oxide (ZnO), indium oxide (In₂O₃), indium gallium oxide (IGO), and aluminum zinc oxide (AZO).

A passivation layer 520 surrounds the micro LED 100 in the recess. The passivation layer 520 covers the recess and the first electrode 510 by filling a space between the bank layer 400 and the micro LED 100. The passivation layer 520 may be made of an organic insulating substance. For example, the passivation layer 520 may be made of acrylic, poly (methyl methacrylate) (PMMA), benzocyclobutene (BCB), polyimide, acrylate, epoxy, polyester, or the like, but is not limited thereto.

The passivation layer 520 is formed to have a height not covering an upper portion of the micro LED 100, for example, a height not covering the second contact electrode 107, such that the second contact electrode 107 is exposed. The second electrode 530 may be formed on the passivation layer 520 electrically connected to the exposed second contact electrode 107 of the micro LED 100.

The second electrode 530 may be disposed on the micro LED 100 and the passivation layer 520. The second electrode 530 may be made of a transparent conductive material such as ITO, IZO, ZnO, In₂O₃, or the like.

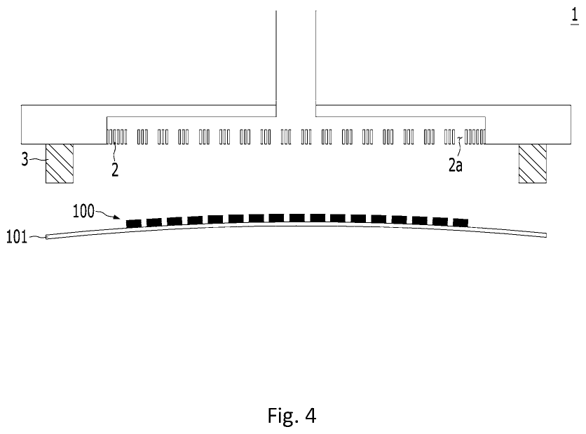

Hereinbelow, a micro LED transfer head 1 for a micro LED according to an embodiment of the present invention will be described with reference to FIG. 4.

FIG. 1 is a view schematically illustrating the micro LED transfer head 1 according to the embodiment of the present invention. As illustrated in FIGS. 3 and 4, the micro LED transfer head 1 according to the present invention includes a holding part 2 holding micro LEDs 100, and a buffer member 3 provided around the holding part 2.

The micro LED transfer head 1 may hold the micro LEDs 100 by use of vacuum holding force. Therefore, the holding force for the micro LEDs 100 formed in the holding part 2 may be a vacuum holding force. The micro LED transfer head 1000 may transfer the micro LEDs 100 of a first substrate (for example, a growth substrate 101) to a second substrate (for example, a display substrate 301) by use of the vacuum holding force.

The holding part 2 for holding the micro LEDs 100 may include a porous member having pores. The holding part 2 may hold or detach the micro LEDs 100 by applying a vacuum to the pores of the porous member or releasing the vacuum applied to the pores.

A vacuum chamber may be provided at an upper portion of the holding part 2. The vacuum chamber is connected to a vacuum port providing or releasing a vacuum. The vacuum chamber functions to apply a vacuum to a plurality of pores of the porous member or release the vacuum applied to the pores in accordance with the operation of the vacuum port. A structure of engaging the vacuum chamber with the porous member is not limited as long as the structure is suitable for preventing gas or air from leaking to other parts when applying the vacuum to the porous member or releasing the applied vacuum.

When holding the micro LEDs 100 with vacuum holding, the vacuum applied to the vacuum chamber is transferred to the plurality of pores of the porous member to generate a vacuum holding force for the micro LEDs 100. Accordingly, a lower surface of the porous member may serve as a holding surface holding the micro LEDs 100.

On the other hand, when detaching the micro LEDs 100, the vacuum applied to the vacuum chamber 1200 is released to remove the vacuum from the plurality of pores of the porous member whereby the vacuum holding force to the micro LEDs 100 is removed.

The porous member includes an anodic oxide film in which pores are formed in a predetermined arrangement. The anodic oxide film denotes a film formed by anodizing a metal that is a base material, and the pores denote pores formed in a process of forming the anodic oxide film by anodizing the metal. For example, when the base metal is aluminum (Al) or an aluminum alloy, the anodization of the base material forms an anodic oxide film consisting of anodized aluminum (Al₂O₃) on a surface of the base material. The anodic oxide film formed as described above includes a barrier layer in which pores are not formed and a porous layer in which the pores are formed. The barrier layer is located on the base material, and the porous layer is located on the barrier layer. After removing the base material on which the anodic oxide film having the barrier layer and the porous layer is formed, only the anodic oxide film consisting of anodized aluminum (Al₂O₃) remains.

The anodic oxide film has the pores configured vertically and having a regular arrangement with a uniform diameter. Accordingly, after removing the barrier layer, the pores have a structure vertically passing through the anodic oxide film from top to bottom, thereby facilitating the generation of the vacuum pressure in a vertical direction.

Due to the pores of vertical shape, air flow paths of vertical shape may be formed inside the anodic oxide film. An internal width of the pores has a size of several to several hundred nanometers. For example, when a size of the micro LEDs to be vacuum-held is 30 μm×30 μm and an internal width of the pores is several nanometers, it is possible to vacuum-hold the micro LEDs 100 by approximately tens of millions of pores.

When a size of the micro LEDs to be vacuum-held is 30 μm×30 μm and an internal width of the pores is several hundred nanometers, it is possible to vacuum-hold the micro LEDs 100 by approximately tens of thousands of pores. The micro LEDs 100 are lightweight because each of the micro LEDs 100 is fundamentally configured with a first semiconductor layer 102, a second semiconductor layer 104, an active layer 103 provided between the first semiconductor layer 102 and the second semiconductor layer 104, a first contact electrode 106, and a second contact electrode 107. Accordingly, it is possible to vacuum-hold the micro LEDs 100 by tens of thousands to tens of millions of pores formed in the anodic oxide film.

Holes 2a may be formed in the anodic oxide film. The holes 2a may be formed by etching the above-described anodic oxide film. Each of the holes 2a may be formed at a position corresponding to each of the micro LEDs 100 of the first substrate 101. The holes 2a are configured to pass through upper and lower surfaces of the anodic oxide film. The holes 2a may be larger in diameter than the pores of the anodic oxide film. Compared with the configuration in which the micro LEDs 100 are vacuum-held by only the pores, it is possible to increase the holding surface area for the micro LEDs 100 due to the configuration in which the holes 2a having a larger diameter than the pores are provided.

The porous member is configured as powders, a coating film, or bulk. The powder may have various shapes such as a sphere, a hollow sphere, a fiber, and a tube. The powder may be used as it is in some cases, but it is also possible to prepare a coating film or a bulk shape with the powder as a starting material.

When the pores of the porous member have a disordered pore structure, air flow paths connecting upper and lower portions of the porous member are formed inside the porous member by the plurality of pores that are connected to each other. On the other hand, when the pores of the porous member have a vertical pore structure, air flow paths that pass through upper and lower portions of the porous member are formed inside the porous member by the pores of vertical shape.

As illustrated in FIG. 4, the buffer member 3 may be provided around the holding part 2. The buffer member 3 may be provided to protrude downwardly further than the holding part 2 at a position around the holding part 2. Due thereto, when the micro LED transfer head 1 is lowered to hold the micro LEDs 100, the micro LED transfer head 1 may first come into contact with an upper surface of the first substrate 101.

The buffer member 3 may be made of a material that can elastically deform. The buffer member 3 may include sponge, rubber, silicone, foam, or the like, and preferably, may be polydimethysiloxane (PDMS). However, the buffer member 3 is not limited to the above configuration.

The buffer member 3 as described above may be provided to have a length larger than heights of the micro LEDs 100 of the first substrate 101 when contracting to a maximum degree by lowering of the micro LED transfer head 1. This may be realized by providing the buffer member 3 in consideration of the degree of contraction of the material constituting the buffer member 3. Therefore, a maximum contraction length of the buffer member 3 may be larger than the heights of the micro LEDs 100 of the first substrate 101. For example, when the heights of the plurality of micro LEDs 100 chipped on the first substrate 101 are different from each other, the maximum shrinkage length of the buffer member 3 may be larger than a height of a micro LED having a highest height on the first substrate 101.

The buffer member 3 as described above is elastically deformed to the maximum contraction length, thereby preventing excessive lowering of the micro LED transfer head 1 and damage to the micro LEDs 100.

Specifically explained, a transfer head 1000, which is a technology underlying the present invention, is lowered to hold micro LEDs 100 of a first substrate 101 in which warpage has occurred, with different lowering positions relative to respective micro LEDs 100. In this case, the transfer head 1000 first holds a micro LED 100 located at a highest position of the first substrate 101 due to the warpage of the first substrate 101. The transfer head 1000 is then lowered further to hold the other micro LEDs 100 which remain on the first substrate 101 without being held. Herein, the micro LED 100 first held on the holding part 2 is excessively pressurized by lowering of the transfer head 1000. This may result in a problem of damage to the micro LEDs 100.

However, the micro LED transfer head 1 according to the present invention may be lowered by a distance equal to the maximum contraction length of the buffer member 3 through provision of the buffer member 3 that protruding further than the holding part 2 at a position around the holding part 2. This may limit the lowering position of the micro LED transfer head 1. As a result, it is possible for the micro LED transfer head 1 to hold the micro LEDs 100 of the first substrate 101 in which the warpage has occurred without causing damage to the micro LEDs.

In addition, the buffer member 3 according to the present invention may pressurize and deform the first substrate 101 in which the warpage has occurred while contracting to the maximum contraction length. In this case, the buffer member 3 may be lower in modulus of elasticity than the first substrate 101.

In the case of the first substrate 101, when a crying warpage or a smiling warpage occurs, the first substrate 101 may warp toward a micro LED presence region existing on the first substrate 101. The buffer member 3 may be provided at a position corresponding to the peripheral portion of the micro LED presence region on the first substrate 101 while being around the holding part 2, such that the buffer member 3 may increase the flatness of the first substrate 101 while pressing and deforming the first substrate 101. This makes it possible to further increase the efficiency of holding the micro LEDs 100, which have different heights due to the warpage of the first substrate 101.

On the other hand, the buffer member 3 may pressurize and deform the first substrate 101 after contracting to the maximum contraction length.

According to the present invention, with the provision of the buffer member 3 as described above, it is possible to create an environment which enables efficient and collective holding of the micro LEDs 100 while alleviating the warpage of the first substrate 101.

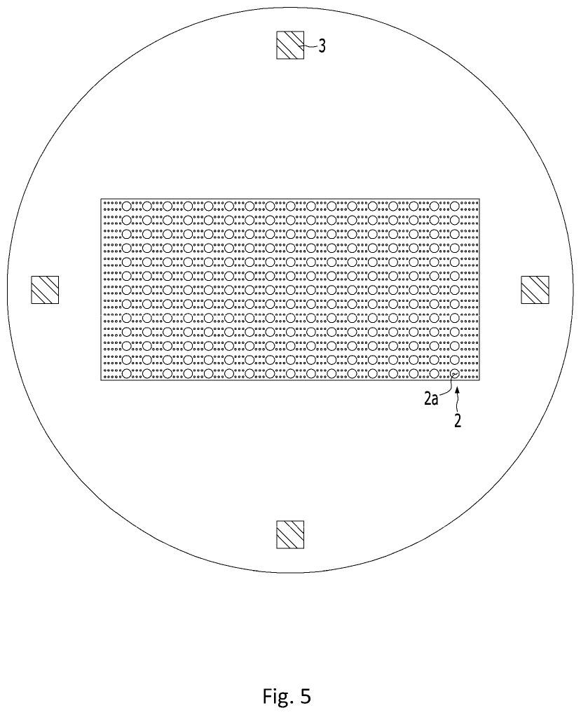

FIG. 5 is a view illustrating the micro LED transfer head 1 according to the present invention when viewed from below. As illustrated in FIG. 5, the buffer member 3 may be provided discontinuously around the holding part 2. In this case, in FIG. 5, one buffer member 3 is provided around each of the left, right, upper, and lower sides (in the drawing of FIG. 5) of the holding part 2. However, the number of the buffer members 3 provided discontinuously around the holding part 2 is not limited thereto.

The buffer member 3 may be provided in a form discontinuously around the holding part 2. As illustrated in FIG. 5, the buffer member 3 may be provided discontinuously around each of the left, right, upper, and lower sides (in the drawing) of the holding part 2, such that a plurality of buffer members 2 may be arranged in a discontinuous arrangement around the holding part 2.

The buffer members 3 may contract by coming into contact with the upper surface of the first substrate 101 when the micro LED transfer head 1 is lowered. Since the buffer members 3 are arranged in a discontinuous arrangement around the holding part 2 at positions around the left, right, upper, and lower sides (in the drawing) of the holding part 2, it is possible to uniformly alleviate the warpage of the first substrate 101. Due thereto, it is possible to prevent the problem that a part of the micro LEDs 100 in the micro LED presence region of the first substrate 101 is excessively pressurized during the course of holding the micro LEDs 100 by the micro LED transfer head 1, thereby reducing the occurrence rate of damage to the micro LEDs 100. As a result, there is obtained an effect of increasing the efficiency of holding the micro LEDs 100.

On the other hand, the buffer member 3 may be provided continuously around the holding part 2. The buffer member 3 may have a shape that is provided continuously around the holding part 2 along the periphery thereof. For example, when the holding part 2 is provided in a shape having a rectangular cross-section, the buffer member 3 may have a shape provided continuously around a rectangle along the periphery thereof. Alternatively, when the holding part 2 is provided in a shape having a circular cross-section, the buffer member 3 may have a shape that is provided continuously around a circle along the periphery thereof. However, this is only one exemplary embodiment of the buffer member 3, and thus the shape of the buffer member 3 is not limited thereto. The buffer member 3 may be provided continuously around the holding part 2 in a suitable form.

The buffer member 3 provided continuously around the holding part 2 may uniformly pressurize and deform the edge of the first substrate 101 in which the warpage has occurred. Herein, the edge of the first substrate 101 may be the peripheral portion of the micro LED presence region existing on the first substrate 101.

The crying warpage or the smiling warpage occurring in the first substrate 101 may occur when the first substrate 101 warps toward the micro LED presence region of the first substrate 101. The buffer member 3 provided continuously around the holding part 2 may uniformly press and deform the peripheral portion of the micro LED presence region of the first substrate 101 as described above. Due thereto, it is possible to more effectively alleviate the warpage of the first substrate 101. As a result, it is possible to prevent the problem that a part of the micro LED presence region of the first substrate 101 is excessively pressurized due to the warpage of the first substrate 101, leading to damage to the micro LEDs 100.

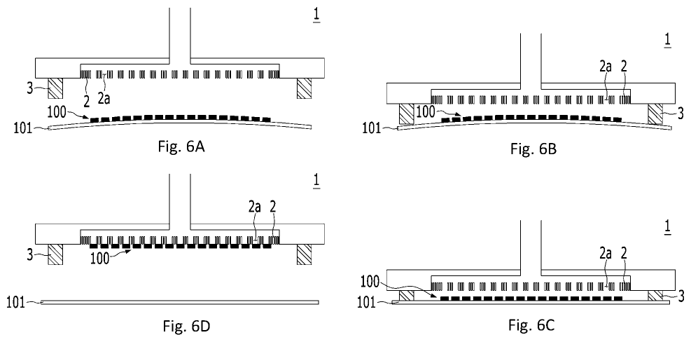

FIGS. 6A to 6D are views schematically illustrating an operation sequence of the micro LED transfer head 1 according to the present invention.

FIG. 6A is a view showing a state before the micro LED transfer head 1 holds the micro LEDs 100 of the first substrate 101 in which the warpage has occurred. As illustrated in FIG. 6A, the buffer members 3 may be provided around the holding part 2. The buffer members 3 may be provided in a shape protruding downwardly further than the holding part 2.

The micro LED transfer head 1 may then be lowered to hold the micro LEDs 100. FIG. 6B is a view illustrating a state in which the micro LED transfer head 1 is lowered so that the lower surfaces of the buffer members 3 is in contact with the upper surface of the first substrate 101. In this case, the buffer members 3 may be in a state before contraction. The buffer members 3 are contact with the upper surface of the first substrate 101 may be contracted by the micro LED transfer head 1 which is further lowered after contact between the buffer members 3 and the first substrate 101. Due to the lowering of the micro LED transfer head 1, the buffer members 3 may be pressurized and contracted, causing the first substrate 101 in which the warpage has occurred to be pressed and deformed. Herein, when the buffer members 3 press and deform the first substrate 101 in which the warpage has occurred while being contracted due to the lowering of the micro LED transfer head 1, the buffer members 3 may be lower in modulus of elasticity than the first substrate 101.

Due to the lowering the micro LED transfer head 1, the buffer members 3 may be contracted to the maximum contraction length. FIG. 6C is a view illustrating a state in which the buffer members 3 are contracted to the maximum contraction length by the lowering of the micro LED transfer head 1. As illustrated in FIG. 6C, the buffer members 3 may reach the maximum contraction length by pressurizing of the micro LED transfer head 1, thereby limiting the lowering position of the micro LED transfer head 1. The buffer members 3, which have reached the maximum contraction length, are no longer contracted, thereby preventing excessive lowering of the micro LED transfer head 1. The buffer members 3 may be contracted to the maximum contraction length while pressing and deforming the first substrate 101 in which the warpage has occurred. The micro LED transfer head 1 of which the lowering position is limited by the buffer members 3 may not cause the problem of damage to the micro LEDs 100 of the first substrate 101.

In FIG. 6C, the micro LED transfer head 1 of which the lowering position is limited by the buffer members 3 holds the micro LEDs 100 in a state of being spaced apart from upper surfaces of the micro LEDs 100. However, the micro LED transfer head 1 may hold the micro LEDs 100 by coming into contact with the upper surfaces of the micro LEDs 100. In other words, the buffer members 3 may be contracted to the maximum contraction length while forming a separation distance between the micro LED transfer head 1 and the micro LEDs 100, or may be contracted to the maximum contraction length such that the holding surface of the holding part 2 of the micro LED transfer head 1 comes into contact with the upper surfaces of the micro LEDs 100.

When the buffer members 3 are contracted to form the separation distance between the micro LED transfer head 1 and the micro LEDs 100 as illustrated in FIG. 6C, this may be effective in terms of preventing micro LED damage.

On the other hand, when the buffer members 3 are contracted such that the holding surface and the upper surfaces of the micro LEDs 100 come into contact with each other, this may be more effective in terms of micro LED holding. The buffer members 3 may be contracted to a height capable of causing the holding surface and the micro LEDs 100 to facilitate holding of the micro LEDs 100 by the micro LED transfer head 1, while performing a buffer function.

FIG. 6D is a view illustrating a state in which the micro LED transfer head 1 according to the present invention with the micro LEDs 100 held is lifted. The micro LEDs 100 held on the micro LED transfer head 1 of which the lowering position is limited by the buffer members 3 in FIG. 6C may be subjected to a laser-lift-off (LLO) process. When the micro LEDs 100 are detached by performing the LLO process, the first substrate 101 may be the growth substrate 101. On the other hand, when the first substrate 101 is a carrier substrate, heat or electromagnetic waves may be used to remove adhesive force acting on the micro LEDs 100 of the first substrate 101, causing the micro LEDs 100 to be detached. The micro LED transfer head 1 which has held the micro LEDs 100 of the first substrate 101 as illustrated in FIG. 6D may transfer the micro LEDs 100 to the second substrate.

The micro LED transfer head 1 according to the present invention can effectively hold micro LEDs of a first substrate 101 having a low flatness, in addition to the first substrate 101 in which the warpage has occurred illustrated in FIG. 4 and FIGS. 6A, 6B, 6C, and 6D.

When the flatness of the first substrate 101 on which the micro LEDs are chipped is low, the micro LED transfer head 1 according to the present invention may control the flatness of the first substrate through the buffer members 3. At least a part of the buffer members 3 may come into contact with an upper surface of the first substrate 101 having a low flatness. At least a part of the buffer members 3 which is first in contact with the first substrate 101 may be contracted to press and deform the first substrate 101 that is in contact therewith. While the flatness of the first substrate 101 is controlled by at least a part of the buffer members 3 which is first in contact with the first substrate 101, a remaining uncontacted part of the buffer members 3 and the first substrate 101 may come into contact with each other. Due thereto, it is possible to create an environment in which the micro LED transfer head 1 can efficiently hold the micro LEDs 100 of the first substrate 101 having a low flatness.

The micro LED transfer head 1 according to the present invention includes the buffer members 3 made of an elastically deformable material around the holding part 2. In the present invention, it is possible to limit the lowering position of the micro LED transfer head 1 by controlling the amount of pressing of the buffer members 3 as described above. This makes it possible to prevent excessive lowering of the micro LED transfer head 1, thereby preventing the problem of damage to the micro LEDs 100.

In addition, since the buffer members 3 are contracted while increasing the flatness of the first substrate 101 in which the warpage has occurred, it is possible to create an environment that enables efficient holding of the micro LEDs 100 without causing damage.

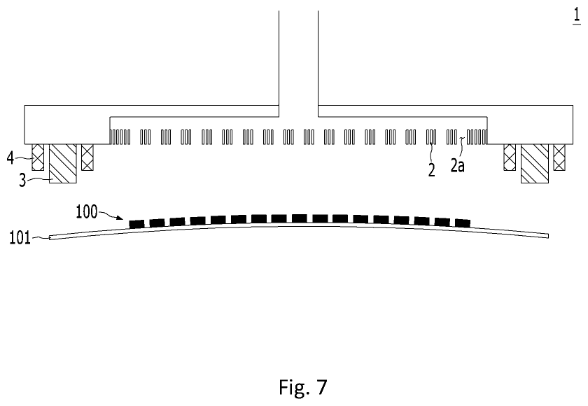

FIG. 7 is a view schematically illustrating a micro LED transfer head 1 according to a first modification of the present invention. The first modification is different from the first embodiment in that a stop member 4 that can limit the amount of pressing of a buffer member 3 is provided around the buffer member 3.

As illustrated in FIG. 7, the micro LED transfer head 1 according to the first modification may include a holding part 2, buffer members 3, and stop members 4.

The buffer members 3 may be provided to protrude downwardly further than the holding part 2 at positions around the holding part 2. The stop members 4 that can limit the amount of pressing of the buffer members 3 may be provided around the buffer members 3.

The stop members 4 may be provided at a height lower than that of the buffer members 3. In other words, the buffer members 3 may be provided to protrude downwardly further than the stop members 4. Since the stop members 4 have a lower height than the buffer members 3, there may be a height difference between the buffer members 3 and the stop members 4. Due to the stop members 4 having a lower height than the buffer members 3, it is possible to limit the amount of pressing of the buffer members 3 which first come into contact with an upper surface of a first substrate 101 when the micro LED transfer head 1 is lowered.

The stop members 4 may be made of a material having a lower modulus of elasticity than the buffer members 3. The buffer members 3 may be made of a material having a high modulus of elasticity as opposed to the stop members 4. In other words, the stop members 4 have a property that is not easily deformed in response to application of an external force, while the buffer members 3 have a property that can be deformed relatively easily in response to application of an external force. In this case, when the micro LED transfer head 1 is lowered, the buffer members 3 which first come into the upper surface of the first substrate 101 before the stop members 4 may be contracted by an amount equal to the height difference with the stop members 4. Due to the buffer members 3 contracted by the amount equal to the height difference with the stop members 4, lower surfaces of the stop members 4 may come into contact with the first substrate 101. Herein, since the stop members 4 hardly contract due to the property of having a low modulus of elasticity, it is possible to stop the contraction of the buffer members 3. In other words, the stop member 4 having a low modulus of elasticity can limit the amount of pressing of the buffer members 3.

The stop members 4 can limit a lowering position of the micro LED transfer head 1 by limiting the amount of pressing of the buffer members 3. This makes it possible to prevent the problem that the micro LEDs 100 may be damaged due to excessive lowering of the micro LED transfer head 1.

In addition, the stop members 4 may contribute to allow the buffer members 3 to more effectively perform the function of alleviating warpage and flatness control of the first substrate 101. While the buffer members 3 are contracted, the warpage of the first substrate 101 may be alleviated or the flatness thereof may be controlled. While the buffer members 3 are contracted by the amount equal to the height difference with the stop members 4, the buffer members 3 may primarily perform warpage alleviation and flatness control of the first substrate 101. After the buffer members 3 are contracted by the amount equal to the height difference with the stop members 4, the stop members 4 may come into contact with the upper surface of the first substrate 101 to secondarily perform the warpage alleviation and flatness control of the first substrate 101. This makes it possible for the micro LED transfer head 1 to perform a process in an environment which enables efficient holding of the micro LEDs 100. As a result, there is obtained an effect of increasing the efficiency of holding the micro LEDs 100.

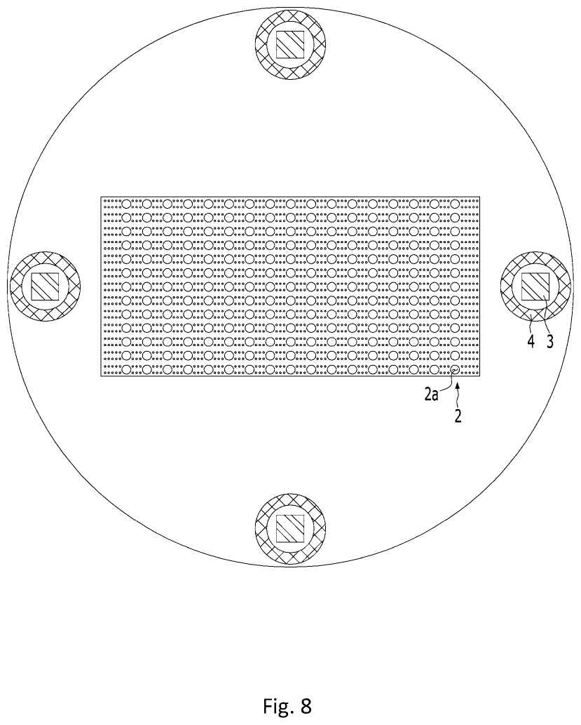

FIG. 8 is a view illustrating the micro LED transfer head 1 according to the first modification when viewed from below. As illustrated in FIG. 8, each of the stop members 4 may be provided continuously along the periphery of each of the buffer members 3 at a position around the buffer member 3. In FIG. 8, the stop member 4 having a circular cross-section is provided continuously along the periphery of the buffer member 3 having a quadrangular cross-section at the position around the buffer member 3. However, the shape of the stop member 4 is not limited thereto.

On the other hand, the stop member 4 may be provided discontinuously around the buffer member 3. When the stop member 4 is provided discontinuously around the buffer member 3, preferably at least two stop members may be provided. The at least two stop members 4 that are provided discontinuously around the buffer member 3 may be arranged respectively at the left and right sides (in the drawing of FIG. 8) or at the upper and lower sides of the buffer member 3. This makes it possible to more effectively limit the amount of pressing of the buffer members 3 when the buffer members 3 are contracted by the amount equal to the height difference with the stop members 4.

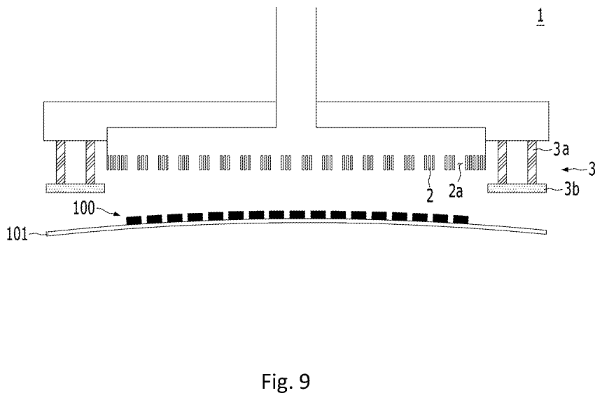

FIG. 9 is a view schematically illustrating a micro LED transfer head 1 according to a second modification of the present invention. The second modified example is different from the first embodiment in that a buffer member 3 provided around a holding part 2 is comprised of a deformable portion 3a and a support portion 3b.

As illustrated in FIG. 9, the micro LED transfer head 1 according to the second modification includes buffer members 3 protruding further than the holding part 2 at positions around the holding part 2.

Each of the buffer members 3 may be comprised of the deformable portion 3a made of a material having a high modulus of elasticity and the support portion 3b made of a material having a low modulus of elasticity. In FIG. 9, the deformable portion 3a is comprised of a first deformable post and a second deformable post. The number of the deformable posts constituting the deformable portion 3a is not limited thereto.

The deformable portion 3a may be made of a deformable post made of an elastically deformable material. When the buffer members 3 come into contact with a first substrate 101 in which warpage has occurred and having a low flatness, the buffer members 3 perform a buffering function by the respective deformable portions 3a and press and deform the first substrate 101.

The support portion 3b is made of a material having a low modulus of elasticity and may be coupled to a lower portion of the deformable portion 3a. The support portion 3b may support the deformable portion 3a on an upper surface thereof. The support part 3b may be coupled to the lower portion of the deformable portion 3a to come into direct contact with an upper surface of the first substrate 101.

As illustrated in FIG. 9, the buffer members 3 protruding downwardly further than a holding surface of the holding part 2 may be greater in height than micro LEDs 100 on the first substrate 101. Due thereto, when the deformable portions 3a are deformed to a maximum contraction length, it is possible to prevent the problem that the holding surface may excessively pressurize the micro LEDs 100, thereby causing damage thereto.

When the deformable portions 3a are deformed to the maximum contraction length, the support portions 3b may alleviate the warpage of the first substrate 101 and control the flatness thereof. Since the support portions 3b have a low modulus of elasticity, the support portions 3b can more effectively perform warpage alleviation and flatness control of the first substrate 101.

Each of the buffer members 3 is comprised of the deformable portion 3a and the support portion 3b to simultaneously have elastic and rigid characteristics. This makes it possible to more effectively implement the buffering function of the micro LED transfer head 1 and a physical limitation of the lowering position of the micro LED transfer head 1.

As described above, the present invention has been described with reference to the exemplary embodiments. However, those skilled in the art will appreciate that various modifications, additions and substitutions are possible, without departing from the scope and spirit of the invention as disclosed in the accompanying claims.

What is claimed is:

1. A micro LED transfer head transferring a micro LED from a first substrate to a second substrate, the micro LED transfer head comprising:
a holding part holding the micro LED; and
a buffer member provided around the holding part and protruding downwardly further than the holding part.

2. The micro LED transfer head of claim 1, wherein the buffer member is provided discontinuously around the holding part.

3. The micro LED transfer head of claim 1, wherein the buffer member is provided continuously around the holding part.

4. The micro LED transfer head of claim 1, wherein the buffer member is polydimethysiloxane (PDMS).
